(19) United States
(12) Patent Application Publication
(10) Pub. No.: US 2014/0028336 A1
(43) Pub. Date: Jan. 30, 2014

(54) PRINTED CIRCUIT BOARD

(71) Applicant: SAMSUNG ELECTRO-MECHANICS CO., LTD., Suwon (KR)

(72) Inventors: Sang Yoon LEE, Sejong (KR); Kyoung Ro Yoon, Sejong (KR); Kwang Seop Youm, Sejong (KR)

(73) Assignee: SAMSUNG ELECTRO-MECHANICS CO., LTD., Suwon (KR)

(21) Appl. No.: 13/952,206

(22) Filed: Jul. 26, 2013

(30) Foreign Application Priority Data
Jul. 27, 2012 (KR) 10-2012-0082752

(51) Int. Cl. G01R 31/28

(52) U.S. Cl. CPC G01R 31/2843
USPC 324/750.3

(57) ABSTRACT

Disclosed herein is a printed circuit board. In the printed circuit board provided with a router machining line to be partitioned into a unit region in which a plurality of unit substrates are formed and a dummy region enclosing the unit region, the unit region and the dummy region are formed in a plurality of layers and the printed circuit board includes detection coupons formed on each of the plurality of layers.

This application claims the benefit under 35 U.S.C. Section 119 of Korean Patent Application Serial No. 10-2012-0082752 entitled “Printed Circuit Board” filed on Jul. 27, 2012, which is hereby incorporated by reference in its entirety into this application.

### BACKGROUND OF THE INVENTION

1. Technical Field

The present invention relates to a printed circuit board, and more particularly, to a printed circuit board capable of detecting inter-layer eccentricity that is a defect occurring due to a mismatch during a process of manufacturing a multi-layer printed circuit board.

2. Description of the Related Art

In general, a printed circuit board (PCB) is one of the most basic parts used for electronic communication devices, and the like. In recent, as electronic products are small and light due to miniaturization, thinness, high densification, packaging, and portability, the printed circuit board has simultaneously been subjected to multilayering by which a circuit layer is formed in plural, fine patterning by which a circuit pattern is miniaturized, miniaturization, and packaging. Therefore, in order to increase fine pattern formation, reliability, and design density of the printed circuit board, the printed circuit pattern tends to have a structure in which a layer configuration of a circuit is complicated according to the change of raw materials and to have the increased mounting density according to the change of a part type from a dual in-line package (DIP) type to a surface mount technology (SMT) type.

As the printed circuit board, there are a single-sided printed circuit board in which wirings are formed only on one side of an insulating substrate, a double-sided printed circuit board in which wirings are formed on both sides, and a multilayered board (MLB) in which wirings are formed in a multilayer.

Herein, as the multilayered board (MLB) in which a wiring layer is additionally formed to expand a wiring region, a multilayered board (inner layer configured of two layers, outer layer configured of two layers) having a four-layer structure that is divided into an inner layer and an outer layer and is formed by bonding the inner layer and the outer layer with a prepreg has been basically used. In this case, as the complexity of the circuit increases, the multilayered board (MLB) may be configured of 6 layers, 8 layers, 10 layers or more.

The multilayered board having the foregoing structure is manufactured to have the inner layer configured of two layers by forming wirings on both sides using a copper clad laminate (CCL) and connecting inter-layer wirings using a via. Next, the multilayered board is manufactured by stacking a prepreg and a copper clad to be formed as an outer layer in an inner layer material depending on design specifications, while matching between the prepreg and the copper clad, and repeating the previous process.

In this case, since an operation of stacking a plurality of layers is repeated in the multilayered board, the inter-layer connection may not be made or the adjacent wirings may be short-circuited due to the mismatch. Such a mismatch is called inter-layer eccentricity or eccentricity.

The related art has used X-ray equipment to detect the inter-layer eccentricity. However, a detection method using the X-ray equipment takes much time and consumes costs to detect the inter-layer eccentricity and may not accurately detect the inter-layer eccentric amount.

### SUMMARY OF THE INVENTION

An object of the present invention is to provide a printed circuit board capable of more effectively and accurately detecting inter-layer eccentricity of the printed circuit board.

Another object of the present invention is to provide a printed circuit board capable of accurately identify inter-layer eccentricity of each wiring layer with the naked eye.

According to an exemplary embodiment of the present invention, there is provided a printed circuit board provided with a router machining line to be partitioned into a unit region in which a plurality of unit substrates are formed and a dummy region enclosing the unit region, the unit region and the dummy region being formed in a plurality of layers, the printed circuit board including: detection coupons formed on each of the plurality of layers.

The detection coupon may have a plane shape formed in a ‘V’-letter shape.

The detection coupon may be formed on the router machining line to extend over the unit region and the dummy region.

Widths of sections of each of the detection coupons exposed on a section of the router machining line may be detected to detect eccentricity.

An interval between the detection coupons for each layer exposed on the section of the router machining line widths may be detected to detect eccentricity.

According to another exemplary embodiment of the present invention, there is provided a printed circuit board provided with a router machining line to be partitioned into a unit region in which a plurality of unit substrates are formed and a dummy region enclosing the unit region, the unit region and the dummy region being formed in a plurality of layers, the printed circuit board including: detection coupons formed on each of the plurality of layers; and a plurality of graduated coupons formed on sides of the detection coupons at a predetermined interval.

The detection coupon may have a plane shape formed in a ‘V’-letter shape.

The graduated coupon may be formed to be parallel with the other side of the detection coupon.

### BRIEF DESCRIPTION OF THE DRAWINGS

FIG. 1 is a plan view illustrating a printed circuit board according to an exemplary embodiment of the present invention;

FIG. 2A is an enlarged plan view of the portion “A” of FIG. 1;

FIG. 2B is a cross-sectional view taken along the line I-I′ of FIG. 2A;

FIG. 3A is an enlarged view of the portion “A” of FIG. 1 and is a plan view illustrating a detection coupon of a printed circuit board in which inter-layer eccentricity occurs;

FIG. 3B is a cross-sectional view taken along the line II-II′ of FIG. 3A;

FIG. 4A is a plan view illustrating a printed circuit board according to another exemplary embodiment of the present invention and is a plan view illustrating a detection coupon of the printed circuit board in which the inter-layer eccentricity occurs; and

FIG. 4B is a cross-sectional view taken along the line III-III′ of FIG. 4A.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

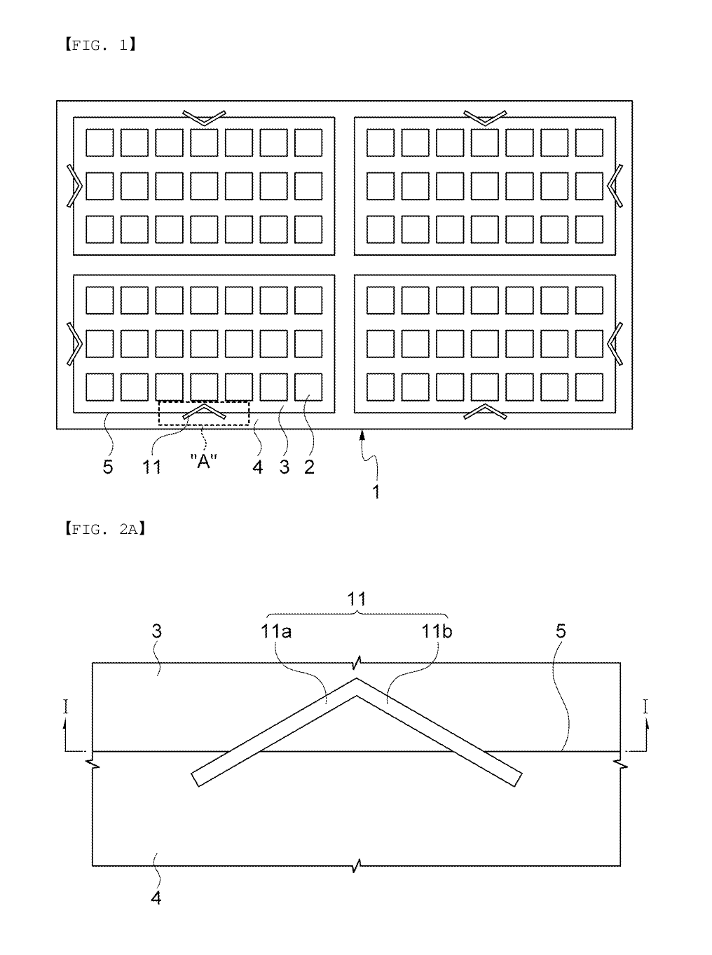

Hereinafter, a printed circuit board according to an exemplary embodiment of the present invention will be described in more detail with reference to FIGS. 1 to 3.

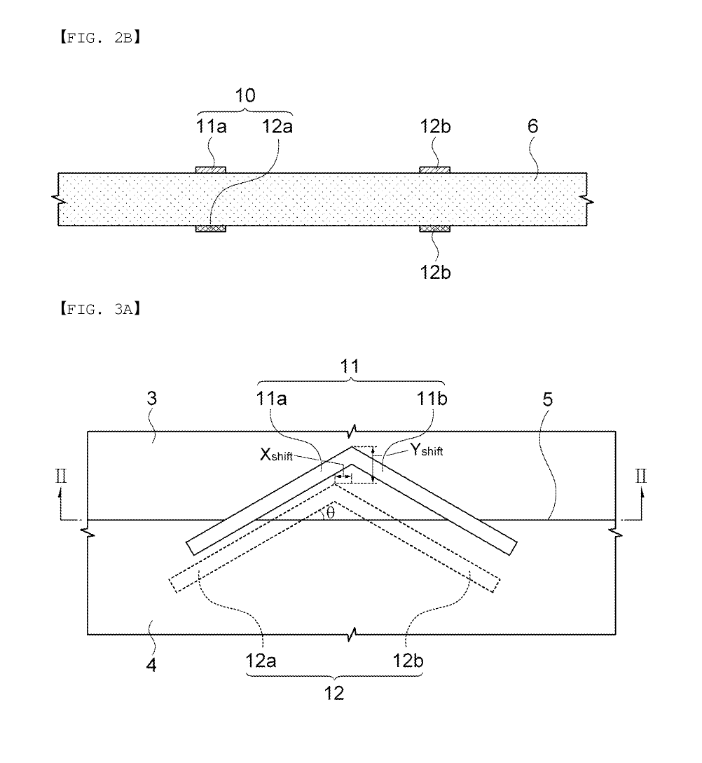

FIG. 1 is a plan view illustrating a printed circuit board according to an exemplary embodiment of the present invention, FIG. 2A is an enlarged plan view of the portion “A” of FIG. 1, and FIG. 2B is a cross-sectional view taken along the line I-I′ of FIG. 2A.

As illustrated in FIGS. 1 to 2B, a printed circuit board 1 according to the exemplary embodiment of the present invention is cut by a router machining after wirings are formed on and beneath a layer (not illustrated), having an insulating layer 6 formed therebetween. However, the exemplary embodiment of the present invention is not limited thereto and may include the appropriate number of circuit layers in consideration of the use field, usage, and the like, of the printed circuit board 1.

Further, the printed circuit board 1 may be configured to include a unit region 3 in which a plurality of unit substrates 2 is formed and a dummy region 4 formed to enclose the unit region 3, wherein a router machining line 5 may be formed to partition the unit region 3 and the dummy region 4 and to be cut by the router machining.

In this configuration, the unit region 3 and the dummy region 4 may be provided with a detection coupon 10.

The detection coupon 10 is to detect inter-layer eccentricity of the printed circuit board 1 on which a plurality of layers are formed and may be formed on each of the plurality of layers. In this case, the detection coupon 10 may be configured of a first detection coupon 11 formed on the insulating layer 6 and a second detection coupon 12 formed beneath the insulating layer 6.

In this configuration, the detection coupon 10 may have a plane shape formed in a “V”-letter shape in which two lines are spread at a predetermined angle based on a vertex.

In this case, the first detection coupon 11 may be formed of a first left detection coupon 11a and a first right detection coupon 11b and the second detection coupon 12 may be formed of a second left detection coupon 12a and a second right detection coupon 12b.

Meanwhile, the detection coupon 10 may be formed on the router machining line 5 to extend over the unit region 3 and the dummy region 4, such that the first detection coupon 11 and the second detection coupon 12 may each be exposed on a section when the detection coupon 12 is machined along the router machining line 5.

That is, the first detection coupon 11 and the second detection coupon 12 are exposed on the section of the router machining line 5, such that the inter-layer eccentricity of the printed circuit board 1 may be simply detected by a simple magnifying glass without X-ray equipment.

In this case, the inter-layer eccentricity of the printed circuit board 1 may be detected depending on the section shape and position of the first detection coupon 11 and the second detection coupon 12.

First, when there is no inter-layer eccentricity in the printed circuit board 1, the first detection coupon 11 and the second detection coupon 12 may be exposed at the same width, the first detection coupon 11 and the second detection coupon 12 exposed on each layer may be aligned in a row in a thickness direction of the printed circuit board 1 to overlap each other, and an interval between the first detection coupon 11 and the second detection coupon 12 may be constantly formed.

That is, when there is no inter-layer eccentricity in the printed circuit board 1, the first detection coupon 11 and the second detection coupon 12 are formed on and beneath the insulating layer 6 to correspond to each other and an interval between the first left detection coupon 11a and the first right detection coupon 11b is formed to be the same as an interval between the second left detection coupon 12a and the second right detection coupon 12b. Further, the first left detection coupon 11a, the first right detection coupon 11b, the second left detection coupon 12a, and the second right detection coupon 12b are formed to have the same width.

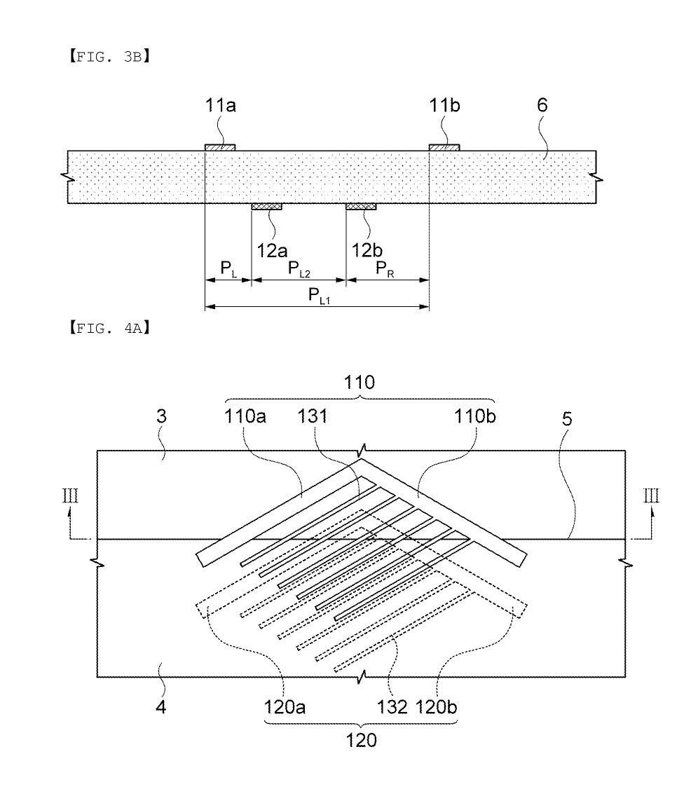

FIG. 3A is an enlarged view of the portion “A” of FIG. 1 and is a plan view illustrating the detection coupon of the printed circuit board in which the inter-layer eccentricity occurs and FIG. 3B is a cross-sectional view taken along the line II-II′ of FIG. 3A.

As illustrated in FIGS. 3A and 3B, when there is the inter-layer eccentricity in the printed circuit board 1, the first detection coupon 11 and the second detection coupon 12 are formed to cross each other and the width of each of the first detection coupon 11 and the second detection coupon 12 and the interval therebetween are formed to be different from each other.

That is, when there is the inter-layer eccentricity in the printed circuit board 1, the first detection coupon 11 and the second detection coupon 12 are formed on and beneath the insulating layer 6 to cross each other and the interval between the first left detection coupon 11a and the first right detection coupon 11b and the interval between the second left detection coupon 12a and the second right detection coupon 12b are formed to be different from each other. Further, the first left detection coupon 11a, the first right detection coupon 11b, the second left detection coupon 12a, and the second right detection coupon 12b are formed to have different widths.

As such, when there is the inter-layer eccentricity in the printed circuit board 1, an eccentric amount may be detected. When an eccentric amount in an X-axis direction is called X_{Shift}, an eccentric amount in a Y-axis direction is called Y_{Shift}, and a total of eccentric amount is called Tatal_{Shift}, Equation measuring the total of eccentric amount may be defined as follows.

$${Y}_{Shift} = \frac{1}{2} \vert {P}_{L 1} - {P}_{L 2} \vert tan θ \\ {X}_{Shift} = \frac{1}{2} \vert {P}_{L 1} - {P}_{L 2} \vert - {P}_{L} = {P}_{R} - \frac{1}{2} \vert {P}_{L 1} - {P}_{L 2} \vert \\ Total Shift = \sqrt{{( {X}_{Shift} )}^{2} + {( {Y}_{Shift} )}^{2}} \qquad [ Equation ]$$

In the above Equation, P_{L1} represents the interval between the first left detection coupon 11a and the first right detection coupon 11b, P_{L2} represents the interval between the second left detection coupon 12a and the second right detection coupon 12b, P_{L} represents the interval between the first left detection coupon 11a and the second left detection coupon 12a, and P_{R} represents the interval between the first right detection coupon 11b and the second right detection coupon 12b. Further, θ is an angle between the first detection coupon 11 or the second detection coupon 12 and the router machining line 5.

Therefore, as described above, the printed circuit board according to the exemplary embodiment of the present invention may detect the inter-layer eccentricity by the detection coupon 10 having a ‘V’-letter shape formed on each layer and detect the eccentric amount depending on the above Equation, thereby more efficiently and accurately detecting the inter-layer eccentricity.

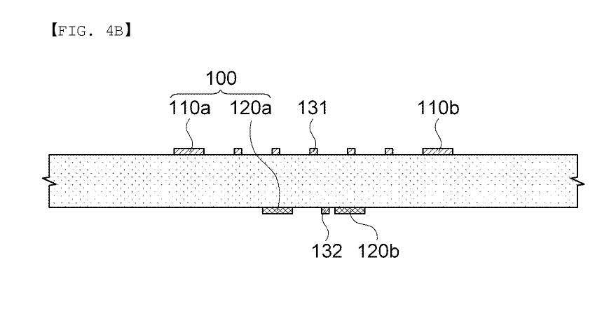

FIG. 4A is a plan view illustrating a printed circuit board according to another exemplary embodiment of the present invention and is a plan view illustrating the detection coupon of the printed circuit board in which the inter-layer eccentricity occurs and FIG. 4B is a cross-sectional view taken along the line of FIG. 4A.

As illustrated in FIGS. 4A and 4B, the printed circuit board according to another exemplary embodiment of the present invention is provided with a router machining line 5 to be partitioned into the unit region 3 in which the plurality of unit substrates 2 is formed and the dummy region 4 enclosing the unit region 3, wherein the unit region 3 and the dummy region 4 are formed in a plurality of layers, and includes a detection coupon 100 formed on each of the plurality of layers and a plurality of graduated coupons 130 formed on sides of the detection coupons 100 at a predetermined interval.

Here, components other than the detection coupon 100 and the graduated coupon 130 are the same as the foregoing embodiments and the detailed description thereof will be omitted.

The detection coupon 100 is to detect the inter-layer eccentricity of the printed circuit board 1 on which a plurality of layers are formed and may be formed on each of the plurality of layers. In this case, the detection coupon 10 may be configured of a first detection coupon 100 formed on the insulating layer 6 and a second detection coupon 120 formed beneath the insulating layer 6.

In this configuration, the detection coupon 100 may have a plane shape formed in a “V”-letter shape in which two lines are spread at a predetermined angle based on a vertex.

In this case, the first detection coupon 110 may be formed of a first left detection coupon 110a and a first right detection coupon 110b and the second detection coupon 120 may be formed of a second left detection coupon 120a and a second right detection coupon 120b.

The graduated coupon 130 may be formed of a first graduated coupon 131 formed in the first detection coupon 110 and a second graduated coupon 132 formed in the second detection coupon 120.

In this configuration, the first graduated coupon 131 is integrally formed in the first right detection coupon 110b and may be formed to be parallel with the first left detection coupon 110a and formed in plural, being spaced apart therefrom at a predetermined interval.

Further, the second graduated coupon 132 is integrally formed in the second right detection coupon 120b to correspond to the first graduated coupon 131 and may be formed to be parallel with the second left detection coupon 120a and formed in plural, being spaced apart therefrom at a predetermined interval.

Meanwhile, the detection coupon 110 may be formed on the router machining line 5 to extend over the unit region 3 and the dummy region 4, such that the detection coupon 100 and the graduated coupon 130 may each be exposed on a section, being spaced apart from each other at a predetermined interval, when the detection coupon 100 is machined along the router machining line 5.

Therefore, in the printed circuit board according to another exemplary embodiment of the present invention, the detection coupon 100 and the graduated coupon 130 are exposed on the section of the router machining line 5, such that the inter-layer eccentricity of the printed circuit board 1 may be simply detected by the simple magnifying glass without the X-ray equipment and the interval between the detection coupons 100 is measured by the graduated coupons 130 formed at a predetermined interval, such that the inter-layer eccentricity may be detected without a separate measurement.

As set forth above, according to the exemplary embodiment of the present invention, the printed circuit board can more effectively and accurately detect the inter-layer eccentricity of each layer using the detection coupon.

Further, the inter-layer eccentricity of each layer can be accurately identified with the naked eye by using the detection coupon and the graduated coupon.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A printed circuit board provided with a router machining line to be partitioned into a unit region in which a plurality of unit substrates are formed and a dummy region enclosing the unit region, the unit region and the dummy region being formed in a plurality of layers, the printed circuit board comprising:
detection coupons formed on each of the plurality of layers.

2. The printed circuit board according to claim 1, wherein the detection coupon has a plane shape formed in a ‘V’-letter shape.

3. The printed circuit board according to claim 2, wherein the detection coupon is formed on the router machining line to extend over the unit region and the dummy region.

4. The printed circuit board according to claim 2, wherein widths of sections of each of the detection coupons exposed on a section of the router machining line are detected to detect eccentricity.

5. The printed circuit board according to claim 2, wherein an interval between the detection coupons for each layer exposed on the section of the router machining line widths is detected to detect eccentricity.

6. A printed circuit board provided with a router machining line to be partitioned into a unit region in which a plurality of unit substrates are formed and a dummy region enclosing the unit region, the unit region and the dummy region being formed in a plurality of layers, the printed circuit board comprising:
detection coupons formed on each of the plurality of layers; and
a plurality of graduated coupons formed on sides of the detection coupons at a predetermined interval.

7. The printed circuit board according to claim 6, wherein the detection coupon has a plane shape formed in a ‘V’-letter shape.

8. The printed circuit board according to claim 6, wherein the graduated coupon is formed to be parallel with the other side of the detection coupon.
